(19) United States
(12) Patent Application Publication
(10) Pub. No.: US 2025/0218812 A1
(43) Pub. Date: Jul. 3, 2025

(54) SUBSTRATE PROCESSING APPARATUS, PHOTOGRAPHING UNIT AND LIQUID PROCESSING CHAMBER

(71) Applicant: SEMES CO., LTD., Cheonan-si (KR)

(72) Inventors: Oh Yeol KWON, Cheonan-si (KR); Soo Yeon SHIN, Suwon-si (KR); Dong Min PARK, Yongin-si (KR)

(73) Assignee: SEMES CO., LTD., Cheonan-si (KR)

(21) Appl. No.: 18/989,131

(22) Filed: Dec. 20, 2024

(30) Foreign Application Priority Data
Dec. 29, 2023 (KR) 10-2023-0197566

(51) Int. Cl. H01L 21/67; G01N 21/88; G06T 7/00; H04N 23/23

(52) U.S. Cl. CPC H01L 21/67051; G01N 21/8806; G06T 7/0004; H01L 21/67253; H04N 23/23; G06T 2207/30148

(57) ABSTRACT

Disclosed is an apparatus for processing a substrate, the apparatus including: a housing providing a processing space; a support unit for supporting a substrate in the processing space; and a photographing unit for photographing the processing space, in which the photographing unit includes: a container mounted on one upper side of the housing, and providing an interior space compartmentalized with the processing space; and a vision provided in the interior space of the container, and photographing the processing space in a downwardly inclined direction.

### CROSS-REFERENCE TO RELATED APPLICATIONS

This application claims priority to and the benefit of Korean Patent Application No. 10-2023-0197566 filed in the Korean Intellectual Property Office on Dec. 29, 2023, the entire contents of which are incorporated herein by reference.

### TECHNICAL FIELD

The present invention relates to a substrate processing apparatus, a photographing unit, and a liquid processing chamber.

### BACKGROUND ART

In order to manufacture semiconductor devices, wet processing, such as cleaning and etching, is performed on substrates, such as wafers. Wet processing includes a batch processing method, which processes multiple substrates by immersing the substrates in a processing tank, and a single-wafer processing method, which processes a substrate by supplying a treatment liquid to one substrate.

In general, in a process chamber that uses the single-wafer processing method, a substrate placed on a chuck is rotated, and a nozzle supplies a treatment liquid to a top surface of the rotating substrate to perform wet processing.

Meanwhile, as semiconductor devices become more dense, highly integrated, and perform better, circuit patterns are rapidly becoming more refined, and precise implementation of wet processing is required. To this end, it is necessary to monitor and inspect the state of the substrate being processed in a process chamber, the state of the nozzle, the state of the treatment liquid discharged from the nozzle, the temperature of the substrate, and the like.

To this end, sensors and lightings are installed in the process chamber to monitor and inspect the substrate, nozzle, treatment liquid, and the like. The sensor obtains an image inside the process chamber. The lighting emits lighting inside the process chamber to help the sensor obtain an image. The sensors and lighting may be installed in multiples.

However, fumes may exist in the process chamber due to the treatment liquid supplied to the substrate. The fumes contaminate the sensors and lighting installed in the process chamber. When the sensors and lighting are contaminated, maintenance/repair work to clean the sensors and the lighting is required. In this case, the worker needs to enter at least a part of his or her body into the process chamber to perform the maintenance/repair work. In this case, the worker is at risk of being exposed to the fumes. In addition, when the sensors and the lightings are installed in multiple different locations, the worker must perform the maintenance/repair work by finding each sensor and lighting, which takes a lot of time for the maintenance/repair work.

In addition, the top surface of the substrate may be flat overall. Accordingly, the light irradiated by the lighting may be reflected from the top surface of the substrate. In other words, lighting reflection may occur from the top surface of the substrate. The lighting reflection may be formed in a pattern shape on the substrate. When lighting reflection occurs, it may be difficult to determine the state of the substrate through the image of the substrate obtained by the sensor.

### SUMMARY OF THE INVENTION

The present invention has been made in an effort to provide a substrate processing apparatus, a photographing unit, and a liquid processing chamber capable of effectively inspecting a process state.

The present invention has also been made in an effort to provide a substrate processing apparatus, a photographing unit, and a liquid processing chamber capable of minimizing the occurrence of lighting reflection in an image or video for inspecting a substrate state.

The present invention has also been made in an effort to provide a substrate processing apparatus, a photographing unit, and a liquid processing chamber capable of effectively obtaining an image or video for inspecting a nozzle state or a treatment liquid state.

The present invention has also been made in an effort to provide a substrate processing apparatus, a photographing unit, and a liquid processing chamber capable of effectively shortening the time required for maintenance/repair work of a photographing unit.

The problem to be solved by the present invention is not limited to the above-mentioned problems, and the problems not mentioned will be clearly understood by those skilled in the art from the descriptions below.

An exemplary embodiment of the present invention provides an apparatus for processing a substrate, the apparatus including: a housing providing a processing space; a support unit configured to support a substrate in the processing space; and a photographing unit configured to photograph the processing space, in which the photographing unit includes: a container mounted on one upper side of the housing, and providing an interior space compartmentalized with the processing space; and a vision provided in the interior space of the container, and photographing the processing space in a downwardly inclined direction.

According to the exemplary embodiment, the container may include: a barrel-shaped body with an open top; and a lead combined with the body to form the interior space, and the lead may be configured to open and close the interior space from an exterior side of the processing space.

According to the exemplary embodiment, the photographing may further include a lighting assembly provided in the container and emitting light in a downwardly inclined direction onto the substrate placed on the support unit.

According to the exemplary embodiment, the lighting assembly may include: a lighting plate; and a plurality of lighting units installed on the lighting plate, and the plurality of lighting units is divided into a plurality of groups, and each of the group may be configured to emit light to a different area of the substrate placed on the support unit.

According to the exemplary embodiment, the lighting plate may be formed with a plurality of angle adjusting units corresponding to the plurality of groups, respectively, and the plurality of angle adjusting units may adjust an irradiation angle of the lighting unit such that a center group of the plurality of groups emits the light to a center area of the substrate, and an edge group of the plurality of groups emits the light to an edge area of the substrate.

According to the exemplary embodiment, the edge groups may be provided in plurality, and the edge groups may emit the light to different edge areas of the substrate.

According to the exemplary embodiment, the apparatus may further include a nozzle configured to discharge a treatment liquid onto the substrate supported on the support unit, in which the photographing unit may include a chamber lighting installed on a lateral wall of the housing and emitting light toward the support unit.

According to the exemplary embodiment, the apparatus may further include a controller configured to control the photographing unit, in which the controller may control the photographing unit in a first mode in which the vision photographs the substrate in a state where the lighting units of the center group, the lighting units of the edge group and the chamber lighting are turned on, when a state of the substrate placed on the support unit is to be inspected.

According to the exemplary embodiment, the apparatus may further include a controller configured to control the photographing unit, in which the controller may control the photographing unit in a second mode in which the vision photographs the nozzle or the treatment liquid in a state where the lighting units of the center group and the chamber lighting are turned on, when a state of the nozzle or the treatment liquid discharged from the nozzle is to be inspected.

According to the exemplary embodiment, the lighting unit may include: a lighting configured to generate the light; and a condenser lens configured to collect the light generated by the lighting.

According to the exemplary embodiment, the lighting plate may be fastened to a front portion of the container facing the processing space by a fixing bolt and an adjusting bolt, an elastic member may be inserted into the adjusting bolt, and the elastic member may be positioned between the container and the lighting plate and is configured to push the lighting plate in a direction away from the front portion of the container.

According to the exemplary embodiment, the fixing bolts may be provided in plural, and one end of the fixing bolt may be inserted into a groove formed in the container, and a tilt angle of the lighting plate may be adjusted according to a degree to which the fixing bolts are inserted into the grooves.

According to the exemplary embodiment, the vision may include: a first vision configured to obtain an image or monitoring video of the processing space; and a second vision configured to obtain a thermal image of the processing space.

According to the exemplary embodiment, the apparatus may further include a controller configured to control the photographing unit, in which the controller may recognize the support unit and/or the substrate placed on the support unit from the monitoring image obtained by the first vision to derive a measurement point, and control the photographing unit to cause the second vision to obtain the thermal image for the measured measurement point.

Another exemplary embodiment of the present invention provides a photographing unit provided to a chamber, the photographing unit including: a container providing an interior space, the interior space being distinct from a processing space of the chamber; a vision provided in the interior space of the container; and a lighting assembly provided in the container, and emitting light to a processing space of the liquid processing chamber in a downwardly inclined direction.

According to the exemplary embodiment, the lighting assembly may include: a lighting plate; and a plurality of lighting units installed on the lighting plate.

According to the exemplary embodiment, the lighting plate may be formed with a plurality of angle adjusting units providing a plane or an inclined surface for a portion of the plurality of lighting units and other portions of the plurality of lighting units to emit the light in different directions.

According to the exemplary embodiment, the lighting unit may include: a lighting configured to generate the light; and a condenser lens configured to collect the light generated by the lighting.

According to the exemplary embodiment, the container may include: a barrel-shaped body with an open top; and a lead combined with the body to form the interior space, and the lead may be configured to open and close the interior space from an exterior side of the processing space.

Still another exemplary embodiment of the present invention provides a liquid processing chamber for liquid-processing a substrate, the liquid processing chamber including: a housing providing a processing space; a support unit configured to support a substrate in the processing space; a nozzle configured to discharge a treatment liquid onto the substrate supported on the support unit; and a photographing unit configured to photograph the substrate placed on the support unit, the nozzle, or the treatment liquid discharged from the nozzle, the photographing unit being controlled by a controller, in which the photographing unit may include: a container installed on one upper side of the housing, and providing an interior space compartmentalized with the processing space; a vision provided in the interior space of the container, and photographing the substrate placed on the support unit in a downwardly inclined direction; a lighting assembly provided in the container and emitting light in the downwardly inclined direction onto the substrate placed on the support unit; and a chamber lighting installed on a lateral wall of the housing and emitting light toward the support unit, the container may include: a barrel-shaped body with an open top; and a lead combined with the body to form the interior space, and the lead is configured to open and close the interior space from an exterior side of the processing space, the lighting assembly may include: a lighting plate; and a plurality of lighting units installed on the lighting plate, and the plurality of lighting units may be divided into a plurality of groups, and each of the group may be configured to emit light to a different area of the substrate placed on the support unit, the lighting plate may be formed with a plurality of angle adjusting units corresponding to the plurality of groups, respectively, and the plurality of angle adjusting units may adjust an irradiation angle of the lighting unit such that a center group of the plurality of groups emits the light to a center area of the substrate, and an edge group of the plurality of groups emits the light to an edge area of the substrate, and the controller may control the photographing unit in any one of a first mode in which the vision photographs the substrate in a state where the lighting units of the center group, the lighting units of the edge group, and the chamber lighting are turned on, when a state of the substrate placed on the support unit is to be inspected, and a second mode in which the vision photographs the nozzle or the treatment liquid in a state where the lighting units of the center group and the chamber lighting are turned on, when a state of the nozzle or the treatment liquid discharged from the nozzle is to be inspected.

According to the exemplary embodiment of the present invention, it is possible to effectively inspect a process state.

Further, according to the exemplary embodiment of the present invention, it is possible to minimize light reflection in images or videos for inspecting a substrate state.

Further, according to the exemplary embodiment of the present invention, it is possible to effectively obtain images or videos for inspecting a nozzle state or a treatment liquid state.

Further, according to the exemplary embodiment of the present invention, it is possible to effectively reduce the time required for maintenance/repair of the photographing unit.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a top plan view of a substrate processing apparatus according to an exemplary embodiment of the present invention.

FIG. 2 is a cross-sectional view illustrating the substrate processing apparatus provided in a process chamber of FIG. 1.

FIG. 3 is a top plan view of the substrate processing apparatus provided in the process chamber of FIG. 1.

FIG. 4 is a diagram illustrating a front portion of a container viewed from the photographing unit of FIG. 2 in direction A.

FIG. 5 is a diagram illustrating a vision and a lighting assembly viewed from the photographing unit of FIG. 2 in direction B.

FIG. 6 is a diagram illustrating a method of fastening a lighting plate and the container.

FIG. 7 is a block diagram illustrating a control mode of the lightings of the photographing unit of the present invention.

FIG. 8 is a diagram illustrating an area where the lighting units emit light to the substrate in the substrate inspection mode.

FIG. 9 is a diagram illustrating the lighting unit and chamber lightings emitting light to a treatment liquid in a liquid discharge inspection mode, viewed from above.

FIG. 10 is a diagram illustrating the chamber lightings emitting light to the treatment liquid in the liquid discharge inspection mode of FIG. 9, viewed from the front.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

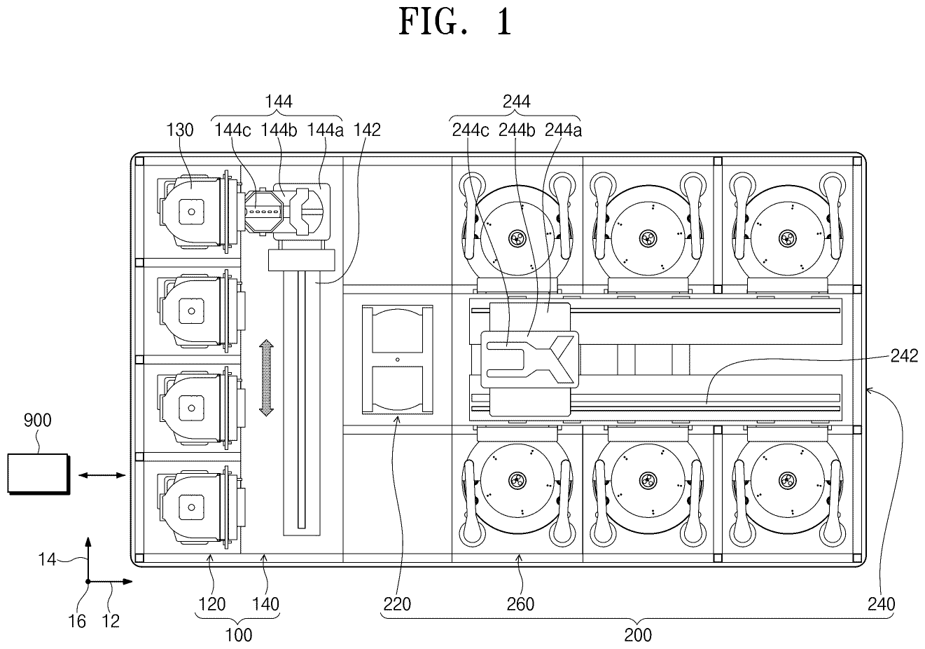

Hereinafter, exemplary embodiments of the present invention will be described in detail with reference to FIGS. 1 to 9.

FIG. 1 is a top plan view of a substrate processing apparatus according to an exemplary embodiment of the present invention.

A substrate processing apparatus 10 includes an index module 100, a process processing module 200, and a controller 900. The Index module 100 includes a load port 120 and a transfer frame 140. The load port 120, the transfer frame 140, and the process processing module 20 are arranged in sequential rows. Hereinafter, a direction in which the load port 120, the transfer frame 140, and the process processing module 200 are arranged is referred to as a first direction 12, a direction perpendicular to the first direction 12 when viewed from above is referred to as a second direction 14, and a direction perpendicular to a plane including the first direction 12 and the second direction 14 is referred to as a third direction 16.

A carrier 130 in which a substrate W is accommodated is seated on the load port 120. A plurality of load ports 120 is provided and is arranged in a line along the second direction 14. The number of load ports 120 may be increased or decreased depending on process efficiency and footprint requirements of the process processing module 200. The carrier 130 is formed with a plurality of slots (not illustrated) for receiving the substrates W in a horizontal position relative to the ground. As the carrier 130, a Front Opening Unified Pod (FOUP) may be used.

The process processing module 200 includes a buffer unit 220, a transfer chamber 240, and a process chamber 260. The transfer chamber 240 may disposed so that a longitudinal direction thereof is parallel to the first direction. The process chambers 260 may be disposed at opposite sides of the transfer chamber 240. On one side of the transfer chamber 240 and on the other side of the transfer chamber 240, the process chambers 260 are provided to be symmetrical with respect to the transfer chamber 240. On one side of the transfer chamber 240, a plurality of process chambers 260 are provided. Some of the process chambers 260 may be disposed in the longitudinal direction of the transfer chamber 240. Further, some of the plurality of process chambers 260 may be disposed to be stacked on each other. That is, the plurality of process chambers 260 may be disposed in an arrangement of A×B at one side of the transfer chamber 240. Here, A is the number of process chambers 260 provided in a line along the first direction 12, and B is the number of process chambers 260 provided in a line along the third direction 16. When four or six process chambers 260 are provided at one side of the transfer chamber 240, the process chambers 260 may be disposed in an arrangement of 2×2 or 3×2. The number of process chambers 260 may be increased or decreased. Unlike the foregoing, the process chamber 260 may be provided only to one side of the transfer chamber 240. In addition, the process chamber 260 may be provided as a single layer on one side and both sides of the transfer chamber 240.

The buffer unit 220 is disposed between the transfer frame 140 and the transfer chamber 240. The buffer unit 220 may provide a space in which the substrate W stays before the substrate W is transferred between the transfer chamber 240 and the transfer frame 140. A slot (not illustrated) in which the substrate W is placed is provided inside the buffer unit 220. A plurality of slots (not illustrated) is provided so as to be spaced apart from each other in the third direction 16. A surface of the buffer unit 220 facing the transfer frame 140 and a surface of the buffer unit 220 facing the transfer chamber 240 may be opened.

The transfer frame 140 transfers the substrate W between the carrier 130 seated at the load port 120 and the buffer unit 220. An index rail 142 and an index robot 144 are provided to the transfer frame 140. A longitudinal direction of the index rail 142 is provided to be parallel to the second direction 14. The index robot 144 is installed on the index rail 142, and linearly moves in the second direction 14 along the index rail 142. The index robot 144 includes a base 144a, a body 144b, and an index arm 144c. The base 144a is installed to be movable along the index rail 142. The body 144b is coupled to the base 144a. The body 144b is provided to be movable in the third direction 16 on the base 144a. Further, the body 144b is provided to be rotatable on the base 144a. The index arm 144c is coupled to the body 144b and is provided to be movable forwardly and backwardly with respect to the body 144b. A plurality of index arms 144c is provided to be individually driven. The index arms 144c are disposed to be stacked in the state of being spaced apart from each other in the third direction 16. Some of the index arms 144c may be used when the substrate W is transferred from the process processing module 20 to the carrier 130, and another some of the plurality of index arms 144c may be used when the substrate W is transferred from the carrier 130 to the process processing module 200. This may prevent particles generated from the substrate W before the process processing from being attached to the substrate W after the process processing in the process of loading and unloading the substrate W by the index robot 144.

The transfer chamber 2400 transfers the substrate W between the buffer unit 2200 and the process chamber 260, and between the process chambers 260. A guide rail 242 and a main robot 244 are provided to the transfer chamber 240. The guide rail 242 is disposed so that a longitudinal direction thereof is parallel to the first direction 12. The main robot 244 is installed on the guide rail 242 and linearly moved along the first direction 12 on the guide rail 242. The main robot 244 includes a base 244a, a body 244b, and a main arm 244c. The base 244a is installed to be movable along the guide rail 242. The body 244b is coupled to the base 244a. The body 244b is provided to be movable in the third direction 16 on the base 244a. Further, the body 244b is provided to be rotatable on the base 244a. The main arm 244c is coupled to the body 244b, and provided to be movable forwardly and backwardly with respect to the body 244b. A plurality of main arms 244c is provided to be individually driven. The main arms 244c are disposed to be stacked in the state of being spaced apart from each other in the third direction 16.

A substrate processing apparatus for performing a liquid processing process on a substrate W is provided in the process chamber 260. The process chamber 260 may be a liquid processing chamber. The substrate processing apparatus may have different structures depending on the type of cleaning process being performed. Alternatively, the substrate processing apparatus within each process chamber 260 may have the same structure. Optionally, the process chambers 260 may be divided into a plurality of groups, such that the substrate processing apparatuses within the process chambers 260 belonging to the same group may have the same structure, and the substrate processing apparatuses provided within the process chambers 260 belonging to different groups may have different structures.

The control unit 900 may include a process controller formed of a microprocessor (computer) that executes the control of the substrate processing apparatus 1, a user interface formed of a keyboard in which an operator performs a command input operation or the like in order to manage the substrate processing apparatus 1, a display for visualizing and displaying an operation situation of the substrate processing apparatus 1, and the like, and a storage unit storing a control program for executing processing performed by the substrate processing apparatus 1 under the control of a process controller, and a program, i.e. a treatment recipe, for executing processing to each component according to various data and processing conditions. Further, the user interface and the storage unit may be connected to the process controller. The processing recipe may be memorized in a storage medium in the storage unit, and the storage medium may be a hard disk, and may also be a portable disk, such as a CD-ROM or a DVD, or a semiconductor memory, such as a flash memory.

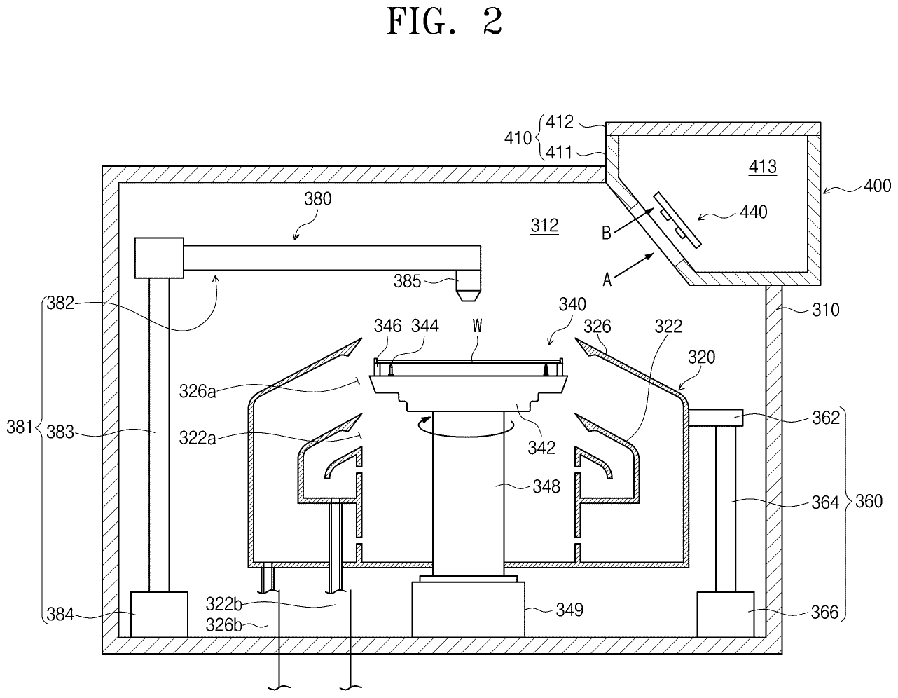

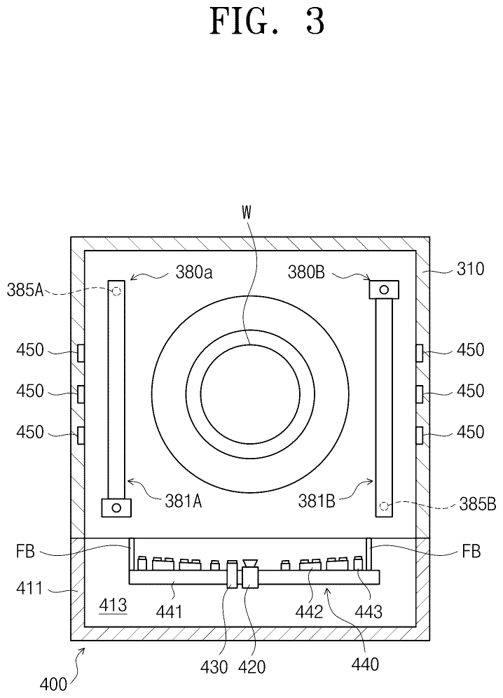

FIG. 2 is a cross-sectional view illustrating the substrate processing apparatus provided in the process chamber of FIG. 1, and FIG. 3 is a top plan view of the substrate processing apparatus provided in the process chamber of FIG. 1.

Referring to FIGS. 2 and 3, the substrate processing apparatus includes a housing 310, a processing container 320, a support unit 340, a lifting unit 360, a liquid supply unit 380, and a photographing unit 400.

The housing 310 has a processing space 312 therein. The housing 310 may have a barrel shape having a space therein. The processing container 320, the support unit 340, the lifting unit 360, and the liquid supply unit 380 may be provided in the interior space 310 of the housing 310. The housing 310 may have a rectangular shape when viewed from the front cross-section. However, the present invention is not limited thereto, and the housing 310 may be deformed into various shapes capable of having the processing space 312.

The processing container 320 has a barrel shape with an open top. The processing container 320 includes an internal recovery container 322 and an external recovery container 326. Each of the recovery containers 322 and 326 recovers different treatment liquids from among the treatment liquids used in the process. The inner recovery container 322 is provided in an annular ring shape surrounding the substrate support unit 340, and the external recovery container 326 is provided in an annular ring shape surrounding the inner recovery container 326. The interior space 322a of the internal recovery container 322 and the internal recovery container 322 function as a first inlet 322a through which the treatment liquid flows into the internal recovery container 322. The space 326a between the internal recovery container 322 and the external recovery container 326 functions as a second inlet 326a through which the treatment liquid flows into the external recovery container 326. In one example, the inlets 322a and 326a may be located at different heights. Recovery lines 322b and 326b are connected below the bottoms of the recovery containers 322 and 326, respectively. The treatment liquids introduced into each of the recovery containers 322 and 326 may be provided to an external treatment liquid regeneration system (not illustrated) through the recovery lines 322b and 326b and be reused.

The support unit 340 supports the substrate W in the processing space 312. The support unit 340 supports and rotates the substrate W during the process. The support unit 340 includes a support plate 342, a support pin 344, a chuck pin 346, and rotation driving members 348 and 349.

The support plate 342 is provided in a substantially circular plate shape, and has an upper surface and a lower surface. The lower surface has a smaller diameter than that of the upper surface. That is, the support plate 342 may have a shape of a narrow upper surface and a narrow lower surface. The upper and lower surfaces are positioned so that their central axes coincide with each other. In addition, a heating means (not illustrated) may be provided on the support plate 342. The heating means provided on the support plate 342 may heat the substrate W placed on the support plate 342. The heating means may generate heat. The heat generated by the heating means may be warm or cold. Heat generated by the heating means may be transferred to the substrate W placed on the support plate 342. In addition, the heat transferred to the substrate W may heat the treatment liquid supplied to the substrate W. The heating means may be a heater and/or a cooling coil. However, the present invention is not limited thereto, and the heating means may be variously modified with known devices.

A plurality of support pins 344 is provided. The support pins 344 are disposed to be spaced apart from each other at predetermined intervals on the edge of the upper surface of the support plate 342 and protrude upwardly from the support plate 342. The support pins 344 are arranged to have an annular ring shape as a whole by combination with each other. The support pins 344 support the rear edge of the substrate W so that the substrate W is spaced apart from the upper surface of the support plate 342 by a predetermined distance.

A plurality of chuck pins 346 is provided. The chuck pin 346 is disposed farther from the center of the support plate 342 than the support pin 344. The chuck pin 346 is provided to protrude upward from the upper surface of the support plate 342. The chuck pin 346 supports the side of the substrate W so that the substrate W is not laterally separated from the original position when the support plate 342 is rotated. The chuck pin 346 is provided to enable linear movement between the outer position and the inner position along the radial direction of the support plate 342. The outer position is a position farther from the center of the support plate 342 compared to the inner position. When the substrate W is loaded or unloaded from the support plate 342, the chuck pin 346 is positioned at the outer position, and when the process is performed on the substrate W, the chuck pin 346 is positioned at the inner position. The inner position is a position where the chuck pin 346 and the lateral portion of the substrate W are in contact with each other, and the outer position is a position where the chuck pin 346 and the substrate W are spaced apart from each other.

The rotation drive members 348 and 349 rotate the support plate 342. The support plate 342 is rotatable about a magnetic center axis by the rotation driving members 348 and 349. The rotation driving members 348 and 349 include a support shaft 348 and a driving unit 349. The support shaft 348 has a barrel shape facing the third direction 16. The upper end of the support shaft 348 is fixedly coupled to the bottom surface of the support plate 342. According to the example, the support shaft 348 may be fixedly coupled to the center of the bottom surface of the support plate 342. The driving unit 349 provides driving force to rotate the support shaft 348. The support shaft 348 is rotated by the driving unit 349, and the support plate 342 is rotatable together with the support shaft 348.

The lifting unit 360 linearly moves the processing container 320 in the up and down direction. As the processing container 320 moves up and down, the relative height of the processing container 320 with respect to the support plate 342 changes. The lifting unit 360 lowers the processing container 320 so that the support plate 342 protrudes above the processing container 320 when the substrate W is loaded onto or unloaded from the support plate 342. In addition, when the process is in progress, the height of the processing container 320 is adjusted so that the treatment liquid is introduced into the predetermined recovery containers 322 and 326 according to the type of the treatment liquid supplied to the substrate W. The lifting unit 460 includes a bracket 362, a moving shaft 364, and a driver 366. The bracket 362 is fixedly installed on the outer wall of the processing container 320, and the moving shaft 364, which is moved in the vertical direction by the driver 366, is fixedly coupled to the bracket 362. Optionally, the lifting unit 360 may move the support plate 342 in the vertical direction.

The liquid supply unit 380 supplies the treatment liquid onto the substrate W. The liquid supply unit 380 may supply a treatment liquid in which plasma is generated to the substrate W. The treatment liquid may be a chemical, a rinsing liquid, a wetting liquid, a cleaning liquid, or an organic solvent. The chemical may be a liquid having acid or basic properties. For example, the chemical may include sulfuric acid (H₂SO₄), phosphoric acid (P₂O₅), hydrofluoric acid (HF), and ammonium hydroxide (NH₄OH). The chemical may be a mixture of Diluted Sulfuric Acid Peroxide (DSP). The cleaning solution, the rinsing liquid, and the wetting solution may be pure water (H₂0). The organic solvent may be isopropyl alcohol (IPA) liquid.

The liquid supply unit 380 may include a moving member 381 and a nozzle 385. The moving member 381 moves the nozzle 385 to a process position and a waiting position. The process position is a position where the nozzle 385 faces the substrate W supported by the support unit 340. According to an example, the process position is a position where the treatment liquid is discharged to the upper surface of the substrate W. Further, the process positon also includes a first supply position and a second supply position. The first supply position may be a position closer to the center of the substrate W than the second supply position, and the second supply position may be a position including an end of the substrate. Optionally, the second supply position may be an area adjacent to the end of the substrate. The waiting position is defined as the position where the nozzle 385 is out of the process position. According to the example, the waiting position may be a position at which the nozzle 385 waits before or after the process processing is completed on the substrate W.

The moving member 381 includes an arm 382, a support shaft 383, and a driver 384. The support shaft 383 is located on one side of the processing container 320. The support shaft 383 has a rod shape whose longitudinal direction faces the third direction. The support shaft 383 is provided to be rotatable by the driver 384. The support shaft 383 is provided to enable lifting and lowering movement. The arm 382 is coupled to the upper end of the support shaft 383. The arm 382 extends perpendicularly from the support shaft 383. The nozzle 385 is coupled to a distal end of the arm 382. A liquid supply unit for supplying a treatment liquid to the nozzle 385 may be provided inside the arm 382. Additionally, the nozzle 385 may be coupled to the arm 382 to adjust the angle at which the treatment liquid is discharged to the upper surface of the substrate W. As the support shaft 383 is rotated, the nozzle 382 may swing and move along with the arm 382. The nozzle 385 may be swingably moved to the process position and the waiting position. Optionally, the arm 382 may be provided to enable forward and backward movement in its longitudinal direction. A path along which the nozzle 385 moves when viewed from above may coincide with the central axis of the substrate W at the process position.

In addition, the liquid supply unit 380 may be provided in multiples. For example, the substrate processing apparatus may be provided with a first liquid supply unit 380A and a second liquid supply unit 380B. The first liquid supply unit 380A and the second liquid supply unit 380B may have shapes that are symmetrical to each other with respect to the center of the substrate W when viewed from above.

In addition, the first liquid supply unit 380A may include a first moving member 381A and a first nozzle 385A, and the second liquid supply unit 380B may include a second moving member 381B and a second nozzle 381B.

Hereinafter, the photographing unit 400 of the present invention will be described in detail.

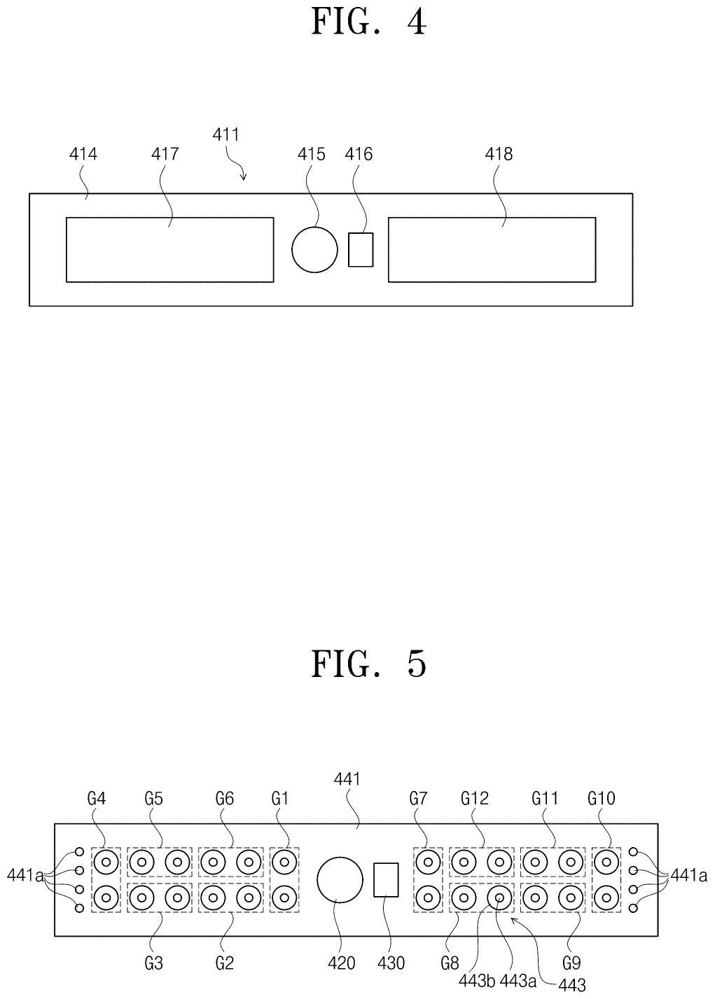

FIG. 4 is a diagram illustrating a front portion of a container viewed from the photographing unit of FIG. 2 in direction A, and FIG. 5 is a diagram illustrating a vision and a lighting assembly viewed from the photographing unit of FIG. 2 in direction B.

The photographing unit 400 according to the exemplary embodiment of the present invention may photograph the processing space 312. The photographing unit 400 may photograph the processing space 312 so as to obtain an image or video including the substrate W placed on the support unit 340 in the processing space 312, the nozzle 385 of the liquid supply unit 380, and a treatment liquid L discharged by the nozzle 385. The photographing unit 400 may obtain an image or video and transmit the obtained image or video to the controller 900. The controller 900 may analyze the image or video obtained by the photographing unit 400 to inspect the process state.

The process state inspected by the controller 900 through the image or video may mean a substrate state, a nozzle state, or a treatment liquid discharge state. The substrate state may mean the presence or absence of the substrate W, a support state of the substrate W, whether the substrate W is damaged, and the like. The nozzle state may refer to the position of the nozzle 385, the misalignment of the nozzle 385, contamination of the nozzle 385, etc. The treatment liquid discharge state may refer to the discharge direction of the treatment liquid L, the discharge thickness of the treatment liquid L, etc.

The photographing unit 400 may include a container 410, a first vision 420, a second vision 430, a lighting assembly 440, and a chamber lighting 450.

The container 410 may be installed on the upper portion of the housing 310. The container 410 may be installed on the upper edge area of the housing 310. The container 410 may include a body 411 having a barrel shape with an open upper portion and a lid 412 covering the upper portion of the body 411. The body 411 and the lid 412 may be combined with each other to provide an interior space 413. The interior space 413 may be a space spatially separated from the processing space 312. Additionally, the body 411 and/or the lid 412 of the container 410 may be formed of a material having excellent corrosion resistance against fume generated by the treatment liquid L in the processing space 312.

A front portion 414 of the container 410 may face the processing space 413. The front portion 414 may be a portion of the body 411. The front portion 414 faces the processing space 312 and may have an inclined surface. A plurality of openings may be formed in the front portion 414, and a plurality of windows may be installed in each opening. For example, a first window 415 corresponding to the first vision 420 described below, a second window 416 corresponding to the second vision 430, a third window 417 corresponding to the lighting unit 443 belonging to a first group to a sixth group G1 to G6, and a fourth window 418 corresponding to the lighting unit 443 belonging to a seventh group to a twelfth group G7 to G12 may be installed in the openings formed in the front portion 414.

The first window 415 may be provided with transparent PVC, the second window 416 may be provided with a germanium window through which infrared rays may be transmitted, and the third and fourth windows 417 and 418 may be provided with transparent PVC.

The lid 412 may cover the body 411. The lid 412 may be provided at a location that is not exposed to the outside of the housing 310, more specifically, the processing space 312. The lid 412 may be configured so that an operator opens and closes the interior space 413 from the outside of the processing space 312. The lid 412 may be provided to be detachable from the body 411, or may be coupled to the body 411 through a hinge member, such as a hinge.

The first vision 420 may be installed to be inserted into an opening formed in the lighting plate 441 described below. The first vision 420 may be configured to photograph the processing space 312 to obtain an image or monitoring image of the processing space. The first vision 420 may obtain an image in the form of unprocessed RAW data and transmit the obtained image to the controller 900 so that the process state of the processing space 312 may be precisely recognized. In addition, the first vision 420 may obtain an image of the processing space 312 as an image with a UHD-level resolution by using the H265 high compression method and transmit the obtained image to the controller 900.

In addition, the nozzle 385 described above may be manufactured from a transparent or translucent material and provided so that an internal path may be observed from the outside. When the treatment liquid L of the nozzle 385 is formed at the end of the nozzle 385, the treatment liquid L may fall down, and to prevent this, the treatment liquid L of the nozzle 385 may be sucked back by using a pressure reducing device or the like. The sucked-back state of the nozzle 385 may also be checked through the image or video obtained by the first vision 420.

The second vision 430 may be installed on one side of the first vision 420. The second vision 430 may obtain a thermal image. The thermal image may be an image that indicates the temperature of the substrate W, or the processing container 320 disposed around the substrate W, the support unit 340, and the like. The second vision 430 may be provided by an infrared thermal imaging camera or the like.

The controller 900 may simultaneously display the monitoring image obtained by the first vision 420 described above and the thermal image obtained by the second vision 430 on a display such as a monitor. For example, the monitoring image may be displayed on the display, and the thermal image may be displayed together with the scale reduced at the right lower end of the monitoring image. Through this, the operator may more effectively recognize the process state.

In addition, the controller 900 may recognize the support unit 340 and/or the substrate W placed on the support unit 340 from the monitoring image and derive a measurement point. The measurement point may be the center point of the substrate W, the edge boundary line of the substrate W, or the edge boundary line of the support unit 340. Through the derived measurement point, the measurement point of the thermal image (i.e., the location and the target within the processing space 312 for which thermal image data is to be obtained through the second vision 430) may be automatically set.

The lighting assembly 440 may emit light into the processing space 312. The lighting assembly 440 may emit light required for the first vision 420 to obtain an image or monitoring image into the processing space 312. The lighting assembly 440 may emit light in a downwardly inclined direction to the substrate W placed on the support unit 340. When the light is emitted in a direction perpendicular to the upper surface of the substrate W, the light may be reflected on the upper surface of the substrate W. In this case, lighting reflection may occur on the upper surface of the substrate W. A portion of the substrate W where the lighting reflection occurs may be brightly illuminated by the light. It may be difficult to clearly recognize the substrate state in the image/video of the substrate W where the lighting reflection occurs due to the brightly illuminated portion.

Therefore, the present invention has an advantage in that the light emitted by the lighting assembly 440 may be irradiated in a downwardly inclined direction, thereby minimizing the occurrence of lighting reflection on the substrate W.

The lighting assembly 440 may include a lighting plate 441 and a lighting unit 443. A longitudinal direction of the lighting plate 441 may be parallel to the direction in which the first liquid supply unit 380A and the second liquid supply unit 380B are arranged. Among the surfaces of the lighting plate 441, the surface on which the lighting unit 443 is installed may be installed so as to be inclined with respect to the processing space 312.

Among the surfaces of the lighting plate 441, a plurality of lighting angle adjusting units 442 may be formed on the surface on which the lighting unit 443 is installed. The lighting angle adjusting unit 442 may adjust the light emission angle of the lighting unit 443. The lighting angle adjusting units 442 may be formed to correspond to the groups of lighting units 443 described below, respectively. For example, as described below, the lighting units 443 may be classified into a first group to a twelfth group G1 to G12, and the lighting angle adjusting unit 442 may be formed on the front surface of the lighting plate 441 to correspond to each of the first group to the twelfth group G1 to G12.

The lighting angle adjusting units 442 may provide inclined surfaces of different angles. In addition, each of the lighting angle adjusting units 442 may provide a plurality of inclined surfaces. In addition, the lighting unit 443 may be installed on each inclined surface.

By the lighting angle adjusting unit 442, the lighting units 443 of the first group G1 and the seventh group G7 belonging to the center group described below may emit light to the central area of the substrate W, and the lighting units 443 of the second to sixth groups G2 to G6 and the eighth to twelfth groups G8 to G12 belonging to the edge group described below may emit light to the edge area of the substrate W.

The lighting unit 443 may emit light to illuminate the processing space 312. The lighting unit 443 may emit light to illuminate the processing space 312 when the first vision 420 obtains an image or a monitoring image (in some cases, when the second vision 430 obtains a thermal image).

The lighting unit 443 may include a lighting 443a which is an LED light source, and a condenser lens 443b. The light generated by the lighting unit 443a may have a very wide irradiation range, but by attaching the condenser lens 443b to the front surface of the lighting 443a, the irradiation range of the light may be narrowed. As the irradiation range of each lighting unit 443 is narrowed, each lighting unit 443 may emit light by targeting a specific area more clearly.

The lighting unit 443 may be divided into a plurality of groups. For example, the lighting unit 443 may be divided into groups of the first to twelfth groups G1 to G12. The lighting units 443 of the first group G1 and the seventh group G7 may emit light to the central area of the substrate W and in a downwardly inclined direction. The first group G1 and the seventh group G7 may be called a center group. The lighting units 443 of the second to sixth groups G2 to G6 and the eighth to twelfth groups G8 to G12 may emit light to the edge area of the substrate W and in a downwardly inclined direction. The second to sixth groups G2 to G6 and the eighth to twelfth groups G8 to G12 may be called an edge group. Each group may be provided with the plurality of lighting units 443. For example, each group may be provided with two lighting units 443.

The chamber lighting 450 may be installed on the lateral wall of the housing 310. The chamber lighting 450 may have a structure substantially the same as or similar to the lighting unit 443 described above. For example, the chamber lighting 450 may be composed of a lighting that is an LED light source and a condenser lens. The chamber light 450 may be provided in plurality. Some of the plurality of chamber lightings 450 may be provided to face one side of the substrate W, and other some may be provided to face the other side of the substrate W. The irradiation range of the chamber lighting 450 may be provided in a range in which light may reach from the nozzle 385 to the substrate W. In addition, the chamber lighting 450 may be embedded in a cavity formed in the inner wall of the housing 310, and the cavity may be shielded by a window, such as the transparent PVC described above, in order to prevent impurities from entering the chamber lighting 450.

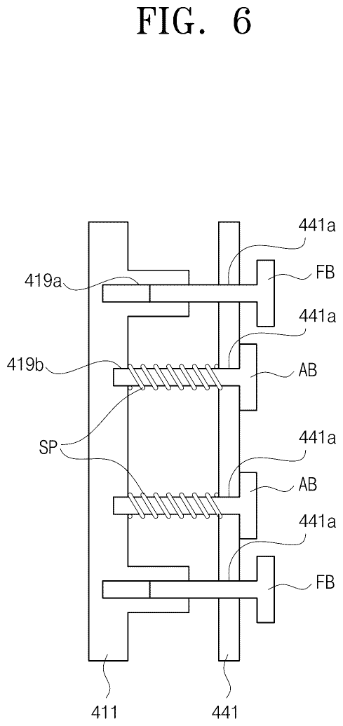

FIG. 6 is a diagram illustrating a method of fastening the lighting plate and the container.

Referring to FIGS. 5 and 6, a plurality of fastening holes 441a may be formed on both sides of the lighting plate 441. A fixing bolt FB and an adjusting bolt AB described later may be inserted into the plurality of fastening holes 441a.

As described above, the lighting plate 441 may be installed in a downwardly inclined direction with respect to the processing space 312. However, the inclined angle of the lighting plate 441 may need to be adjusted as needed.

Accordingly, the photographing unit 400 of the present invention includes a fixed bolt FB and an adjusting bolt AB. First, the adjusting bolt AB may be inserted into the fastening hole 441a, and one end may be fastened to a second groove 419b formed in the body 411. In addition, the adjusting bolt AB may be inserted into an elastic member SP, such as a spring. The elastic member SP is located between the lighting plate 441 and the body 411, and may push the lighting plate 441 away from the body 411.

The fixed bolt FB is inserted into the fastening hole 441a and may be fastened to the first groove 419a formed in the body (411) at one end. A depth of the first groove 419a may be deeper than a depth of the second groove 419b. Therefore, when the operator wants to position the lighting plate 441 closer to the body 411, the operator may fasten the fixed bolt FB deeper into the first groove 419a. Conversely, when the operator wants to position the lighting plate 441 farther from the body 411, the fixed bolt FB may be fastened less deeply into the first groove 419a. A tilt angle of the lighting plate 441 may vary depending on the degrees to which the fixed bolts FB are inserted into the first groove 419a.

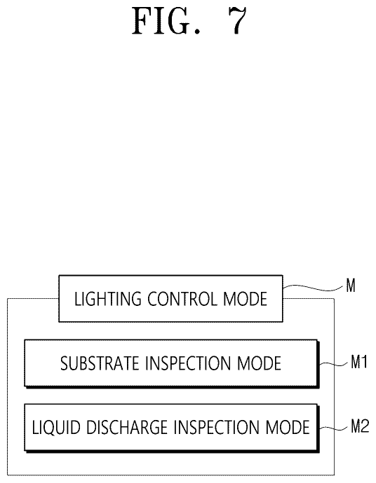

FIG. 7 is a block diagram illustrating a control mode of the lightings of the photographing unit of the present invention.

The controller 900 controls the photographing unit 400 to obtain an image or video for inspecting a process state through any one of two lighting control modes M. The lighting control mode M may include a substrate inspection mode M1 and a liquid discharge inspection mode M2. The substrate inspection mode M1 may be a mode used when obtaining an image or video for inspecting the substrate state described above, and the liquid discharge inspection mode M2 may be a mode used when obtaining an image or video for inspecting the nozzle state and/or the treatment liquid discharge state described above.

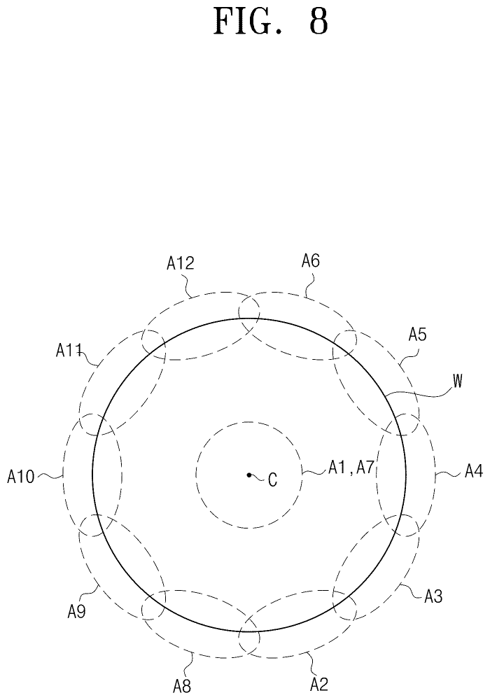

FIG. 8 is a diagram illustrating an area where the lighting units emit light to the substrate in the substrate inspection mode.

Referring to FIG. 8, the substrate inspection mode M1 is performed while the substrate W is placed on the support unit 340. In the substrate inspection mode M1, all lightings of the photographing unit 400 may be turned on. For example, in the substrate inspection mode M1, all of the lighting units 443 of the lighting assembly 440 and the chamber lightings 450 installed in the housing 310 may be turned on.

In this case, the lighting units 443 belonging to the first group G1 emit light to a first area A1, which is the central area of the substrate W, the lighting units 443 belonging to the second group G2 emit light to a second area A2, which is the edge area of the substrate W, the lighting units 443 belonging to the third group G3) emit light to a third area A3, which is the edge area of the substrate W, the lighting units 443 belonging to the fourth group G4 emit light to a fourth area A4, which is the edge area of the substrate W, the lighting units 443 belonging to the fifth group G5 emit light to a fifth area A5, which is the edge area of the substrate W, the lighting units 443 belonging to the sixth group G6 emit light to a sixth area A6, which is the edge area of the substrate W, the lighting units 443 belonging to the seventh group G7 emit light to a seventh area A7, which is the central area of the substrate W, the lighting units 443 belonging to the eighth group G8 emit light to an eighth area A8, which is the edge area of the substrate W, the lighting units 443 belonging to the ninth group G9 emit light to a ninth area A9, which is the edge area of the substrate W, the lighting units 443 belonging to the tenth group G10 emit light to a tenth area A10, which is the edge area of the substrate W, the lighting units 443 belonging to the eleventh group G11 emit light to an eleventh area A11, which is the edge area of the substrate W, and the lighting units 443 belonging to the twelfth group G12 emit light to a twelfth area A12, which is the edge area of the substrate W.

The first area A1 and the seventh area A7 may be substantially the same/similar areas, and the second to sixth areas and the eighth to twelfth areas A2 to A6, and A8 to A12 may overlap to some extent but may be substantially different areas. In addition, in FIG. 8, the areas where light is emitted are illustrated somewhat narrowly in order to easily explain the areas where each group emits light, but in reality, the areas where light is emitted by each group are larger than the areas illustrated in FIG. 8, and thus, light may be emitted to the entire area of the substrate W.

The lighting units 433 belonging to the second to sixth groups G2 to G6 and the eighth to twelfth groups G8 to G12 emit light to different edge areas arranged along the circumferential direction of the substrate W, and only the lighting units 433 belonging to the first group G1 and the seventh group G7 emit light to the central area of the substrate W. When all of the lighting units 433 emit light toward the edge area of the substrate W, the light concentration in the central area of the substrate W occurs more significantly, and in this case, the light reflection phenomenon may occur more prominently. However, in the present invention, the lighting units 433 are classified into a plurality of groups, and the lighting units 433 belonging to each group emit light to different areas of the substrate W, so that the light concentration in a specific area of the substrate W may be alleviated. Through this, the light reflection phenomenon may be minimized from occurring prominently.

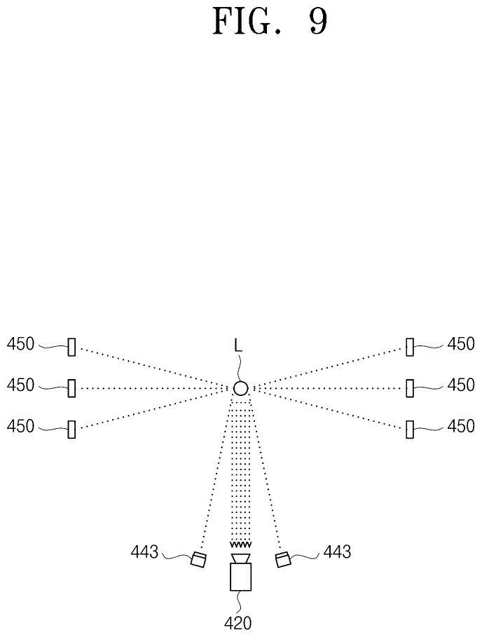

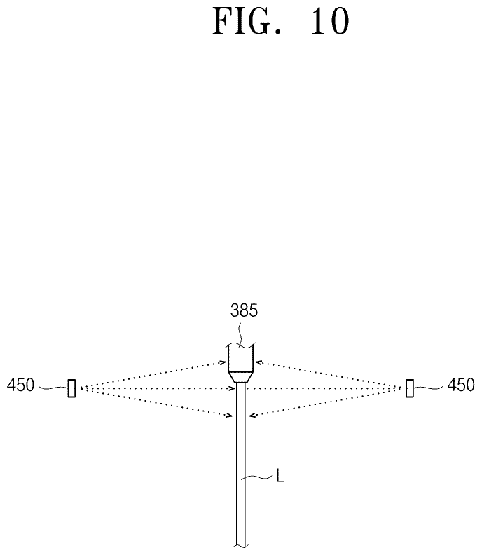

FIG. 9 is a diagram illustrating the lighting unit and chamber lightings emitting light to a treatment liquid in the liquid discharge inspection mode, viewed from above, and FIG. 10 is a diagram illustrating the chamber lightings emitting light to the treatment liquid in the liquid discharge inspection mode of FIG. 9, viewed from the front.

The liquid discharge inspection mode M2 may be performed when the nozzle 385 is positioned at the upper center of the substrate W, or when the nozzle 385 discharges the treatment liquid L to the substrate W. In the liquid discharge inspection mode M2, among the lightings of the photographing unit 400, only the lighting units 443 belonging to the first group G1 and the seventh group G7 and the chamber lightings 450 may be turned on. The lighting units 443 belonging to the remaining groups may be turned off.

Since the nozzle 385 is a rigid body, when the lighting units 443 belonging to the first group G1 and the seventh group G7 and the chamber lighting 450 are turned on, the first vision 420 may obtain an image or video regarding the appearance of the nozzle 385.

In addition, while discharging the treatment liquid L from the nozzle 385, the treatment liquid L generally has a shape of a cylinder and may be supplied to the substrate W. In this case, the light angle adjusting unit 442 of the lighting plate 441 may provide an inclined surface so that the light emitted by the lighting units 443 belonging to the first group G1 and the seventh group G7 may be reflected by the treatment liquid L having a shape of a cylinder and may travel toward the first vision 420. In addition, the light emitted by the chamber lighting 450 may be reflected by the treatment liquid L and may travel toward the first vision 420.

In the substrate inspection mode M1, all lightings of the photographing unit 400 may be turned on. For example, in the substrate inspection mode M1, all of the lighting units 443 of the lighting assembly 440 and the chamber lightings 450 installed in the housing 310 may be turned on.

The photographing unit 400 according to the exemplary embodiment of the present invention may be installed in the upper edge area of the housing 310. The interior space 413 of the photographing unit 400 may be opened and closed by the operator through the lid 412. Therefore, when the operator maintains/repairs the vision and lightings, he/she may maintain and repair most of the equipment related to image/video photographing by maintaining and repairing only the photographing unit 400 from the outside of the housing 310. That is, since the photographing unit 400 is provided separately, the time required for maintenance/repair may be minimized.

In addition, since the visions 420 and 430 and the lighting units 443 are provided in the interior space 413 that is separated from the processing space 312, a high level of explosion-proof design for the visions 420 and 430 and the lighting unit 443 is not required, and therefore the cost required to manufacture the device may also be reduced.

Further, depending on the type of process state to be inspected, the lighting control mode is changed to help more effectively obtain images and videos of the inspection target. In addition, the lighting unit 443 emits light in a downwardly inclined direction and disperses and emits the light to multiple areas of the substrate W, thereby minimizing the problem of light reflection.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

What is claimed is:

1. An apparatus for processing a substrate, the apparatus comprising:
a housing providing a processing space;
a support unit configured to support a substrate in the processing space; and
a photographing unit configured to photograph the processing space,
wherein the photographing unit includes:
a container mounted on one upper side of the housing, and providing an interior space compartmentalized with the processing space; and
a vision provided in the interior space of the container, and photographing the processing space in a downwardly inclined direction.

2. The apparatus of claim 1, wherein the container includes:
a barrel-shaped body with an open top; and
a lead combined with the body to form the interior space, and
the lead is configured to open and close the interior space from an exterior side of the processing space.

3. The apparatus of claim 1, wherein the photographing further includes a lighting assembly provided in the container and emitting light in a downwardly inclined direction onto the substrate placed on the support unit.

4. The apparatus of claim 3, wherein the lighting assembly includes:
a lighting plate; and
a plurality of lighting units installed on the lighting plate, and
the plurality of lighting units is divided into a plurality of groups, and each of the group is configured to emit light to a different area of the substrate placed on the support unit.

5. The apparatus of claim 4, wherein the lighting plate is formed with a plurality of angle adjusting units corresponding to the plurality of groups, respectively, and
the plurality of angle adjusting units adjusts an irradiation angle of the lighting unit such that a center group of the plurality of groups emits the light to a center area of the substrate, and an edge group of the plurality of groups emits the light to an edge area of the substrate.

6. The apparatus of claim 5, wherein the edge groups are provided in plurality, and the edge groups emit the light to different edge areas of the substrate.

7. The apparatus of claim 5, further comprising:
a nozzle configured to discharge a treatment liquid onto the substrate supported on the support unit,
wherein the photographing unit includes a chamber lighting installed on a lateral wall of the housing and emitting light toward the support unit.

8. The apparatus of claim 7, further comprising:
a controller configured to control the photographing unit,
wherein the controller controls the photographing unit in a first mode in which the vision photographs the substrate in a state where the lighting units of the center group, the lighting units of the edge group and the chamber lighting are turned on, when a state of the substrate placed on the support unit is to be inspected.

9. The apparatus of claim 7, further comprising:
a controller configured to control the photographing unit,
wherein the controller controls the photographing unit in a second mode in which the vision photographs the nozzle or the treatment liquid in a state where the lighting units of the center group and the chamber lighting are turned on, when a state of the nozzle or the treatment liquid discharged from the nozzle is to be inspected.

10. The apparatus of claim 5, wherein the lighting unit includes:
a lighting configured to generate the light; and
a condenser lens configured to collect the light generated by the lighting.

11. The apparatus of claim 4, wherein the lighting plate is fastened to a front portion of the container facing the processing space by a fixing bolt and an adjusting bolt,
an elastic member is inserted into the adjusting bolt, and
the elastic member is positioned between the container and the lighting plate and is configured to push the lighting plate in a direction away from the front portion of the container.

12. The apparatus of claim 11, wherein the fixing bolts are provided in plural, and
one end of the fixing bolt is inserted into a groove formed in the container, and a tilt angle of the lighting plate is adjusted according to a degree to which the fixing bolts are inserted into the grooves.

13. The apparatus of claim 1, wherein the vision includes:
a first vision configured to obtain an image or monitoring video of the processing space; and
a second vision configured to obtain a thermal image of the processing space.

14. The apparatus of claim 13, further comprising:
a controller configured to control the photographing unit,
wherein the controller recognizes the support unit and/or the substrate placed on the support unit from the monitoring image obtained by the first vision to derive a measurement point, and controls the photographing unit to cause the second vision to obtain the thermal image for the measured measurement point.

15. A photographing unit provided to a chamber, the photographing unit comprising:
a container providing an interior space, the interior space being distinct from a processing space of the chamber;
a vision provided in the interior space of the container; and
a lighting assembly provided in the container, and emitting light to a processing space of the liquid processing chamber in a downwardly inclined direction.

16. The photographing unit of claim 15, wherein the lighting assembly includes:
a lighting plate; and
a plurality of lighting units installed on the lighting plate.

17. The photographing unit of claim 16, wherein the lighting plate is formed with a plurality of angle adjusting units providing a plane or an inclined surface for a portion of the plurality of lighting units and other portions of the plurality of lighting units to emit the light in different directions.

18. The photographing unit of claim 16, wherein the lighting unit includes:
a lighting configured to generate the light; and
a condenser lens that collecting the light generated by the lighting.

19. The photographing unit of claim 15, wherein the container includes:
a barrel-shaped body with an open top; and
a lead combined with the body to form the interior space, and
the lead is configured to open and close the interior space from an exterior side of the processing space.

20. A liquid processing chamber for liquid-processing a substrate, the liquid processing chamber comprising:
a housing providing a processing space;
a support unit configured to support a substrate in the processing space;
a nozzle configured to discharge a treatment liquid onto the substrate supported on the support unit; and
a photographing unit configured to photograph the substrate placed on the support unit, the nozzle, or the treatment liquid discharged from the nozzle, the photographing unit being controlled by a controller,
wherein the photographing unit includes:
a container installed on one upper side of the housing, and providing an interior space compartmentalized with the processing space;
a vision provided in the interior space of the container, and photographing the substrate placed on the support unit in a downwardly inclined direction;
a lighting assembly provided in the container and emitting light in the downwardly inclined direction onto the substrate placed on the support unit; and
a chamber lighting installed on a lateral wall of the housing and emitting light toward the support unit,
the container includes:
a barrel-shaped body with an open top; and
a lead combined with the body to form the interior space, and
the lead is configured to open and close the interior space from an exterior side of the processing space,
the lighting assembly includes:
a lighting plate; and
a plurality of lighting units installed on the lighting plate, and
the plurality of lighting units is divided into a plurality of groups, and each of the group is configured to emit light to a different area of the substrate placed on the support unit,
the lighting plate is formed with a plurality of angle adjusting units corresponding to the plurality of groups, respectively, and
the plurality of angle adjusting units adjusts an irradiation angle of the lighting unit such that a center group of the plurality of groups emits the light to a center area of the substrate, and an edge group of the plurality of groups emits the light to an edge area of the substrate, and
the controller controls the photographing unit in any one of a first mode in which the vision photographs the substrate in a state where the lighting units of the center group, the lighting units of the edge group, and the chamber lighting are turned on, when a state of the substrate placed on the support unit is to be inspected, and a second mode in which the vision photographs the nozzle or the treatment liquid in a state where the lighting units of the center group and the chamber lighting are turned on, when a state of the nozzle or the treatment liquid discharged from the nozzle is to be inspected.
